(19) United States
(12) Patent Application Publication
(10) Pub. No.: US 2009/0255585 A1
(43) Pub. Date: Oct. 15, 2009

(54) FLEXIBLE PHOTOVOLTAIC DEVICE

(75) Inventors: Mohammed Saleem Shaikh, Santa Ana, CA (US); Mark D. Winsor, Chehalis, WA (US)

Correspondence Address: SEED INTELLECTUAL PROPERTY LAW GROUP PLLC, 701 FIFTH AVE, SUITE 5400, SEATTLE, WA, 98104, US

(73) Assignee: THIN FILM DEVICES, INC., Anaheim, CA (US)

(21) Appl. No.: 12/422,855

(22) Filed: Apr. 13, 2009

Related U.S. Application Data
(60) Provisional application No. 61/044,452, filed on Apr. 11, 2008.

(51) Int. Cl. H01L 31/00; H01L 21/28

(52) U.S. Cl. 136/261; 438/98; 438/82; 257/E21.158

(57) ABSTRACT

An embodiment of a photovoltaic cell forms a barrier layer over a flexible substrate and forms a plurality of parallel lines of N-type semiconductor material directly on the barrier layer. A plurality of parallel lines of P-type semiconductor material are formed directly on the barrier layer and positioned with each line of the plurality of parallel lines of P-type semiconductor material having at least one common longitudinal boundary with one line of the plurality of parallel lines of N-type semiconductor material. A plurality of first conductive bus lines are in longitudinal contact with at least a subset of the plurality of parallel lines of N-type semiconductor material, and a plurality of second conductive bus lines are in longitudinal contact with at least a subset of the plurality of parallel lines of P-type semiconductor material.

### BACKGROUND

1. Technical Field

This invention relates to photovoltaic devices, and in particular, to a solar cell formed on a flexible plastic substrate. The solar cell is used to generate electricity directly from sunlight.

2. Description of the Related Art

Commercially available solar cells are typically constructed from two different photoactive materials. The photoactive materials are often inorganic P-type and N-type semiconductors with bandgaps optimized for solar radiation. The atoms of the semiconductive materials form a junction. When light strikes the photoactive material, one of the semiconductors releases electrons, which are captured as a useful electric charge. The released electrons leave holes in the semiconductor, and the holes are filled by donor electrons crossing the boundary from the other semiconductor. A well established example of the acceptor/donor technology is the silicon single crystal solar cell, sliced into thick wafers, and doped with phosphorous.

Silicon wafer technology doped with phosphorous typically requires high temperatures and special processing during manufacture of the solar cell. The high temperatures limit the choices of available substrate materials to those that can withstand processing at high temperatures. The chosen substrate material is rigid and often expensive.

Thin film solar cells constructed of inorganic materials have been tried, but such cells are more complicated to produce. Thin film photovoltaic cells constructed from inorganic materials rely on nano-sized thin film materials positioned one on top of another. The intimate relationship between the layers produces a layered, thin film architecture. Examples of photovoltaic materials used in conventional thin film solar cells are cadmium sulfide based materials doped with tellurium (CdS:CdTe), copper indium gallium selenide (CIGS), and polycrystalline silicon (poly-Si), among several others. Generally, these thin film solar cells are formed of multiple layers in a simple symmetrical structure of metal, semiconductor, and metal thin film geometry.

Like the thick wafer silicon single crystal solar cell, the thin film semiconductor is separated into acceptor and donor regions. The regions are divided by a single junction interface in a typical planar cell configuration. Photons excite the semiconductor atoms and excite electrons out of the material's bandgap. The photovoltaic reaction produces combinations of free electrons and holes according to quantum band theory.

Problems currently exist with solar cells constructed according to a stacked film cell design. Particularly, the formation of each layer of the cell produces non-uniformities in the layer that manifest as peaks and valleys. Each additional layer of the stack exaggerates the normal film non-uniformity and peak and valley effects of the preceding layer. Major negative effects of the stacked film design come from rough surface morphology of a generally inconsistent crystal structure. The rough surfaces cause reduced or inconsistent charge mobility, which includes charges lost through recombination.

The normal undesirable artifacts of stacked film solar cells affect all thin and thick film deposition technologies known today and cause problems with the resulting solar cell. At the atomic level, the layer of metal and semiconductor produce rough grain boundaries and disordered crystal structures that reduce electron mobility. The resulting solar cell suffers from an increase of electrical losses and the production of heat. As more layers are incorporated into the cell, the problems are compounded. Sometimes, the problems lead to an electrical short circuit of a particular area of the solar cell causing catastrophic failure results.

FIG. 1 illustrates a layered photovoltaic cell constructed from organic materials called an organic photovoltaic solar cell (OPV) cell. FIG. 1 illustrates a cross section of a known OPV cell. The photovoltaic cell of FIG. 1 represents one approach that has been tried to address the problems found in solar cells formed with inorganic photovoltaic materials. Particularly, the cell of FIG. 1 uses a conjugated polymer to construct an organic photovoltaic solar cell (OPV). OPV plastic or carbon based materials provide charge separation by the specific molecular arrangement of the electron configurations within the materials. In operation, moving excitons from the energy gap between the lowest unoccupied molecular orbits (LUMO) and the highest orbital molecular orbits (HOMO) are exploited for electrical production. The theory of electrical production in OPV charge transport mechanisms is different than that of the inorganic semiconductor model, but nevertheless can be thought of in general understanding by way of hole-acceptor and electron-acceptor polymers.

OPV materials can be used with other organic semiconductors to form a vast combination of acceptor and donor interfaces, known as bulk hetrojunction (BHJ) OPV. The combinations may include inorganic P-type and N-type materials. The combinations may be made into mixtures and blended by simple wet chemistry.

The OPV cell of FIG. 1 illustrates a known glass plate substrate 100 having a known OPV cell formed thereon. Upon the substrate 100, a conductive ITO layer 120 is formed and upon the ITO layer 120, a P-type PEDOT layer 140 is formed. A BHJ layer 160 is sandwiched between the PEDOT layer 140 and a lithium-aluminum conductor 180. The LiAl conductor layer 180 is an N-type material.

In operation, solar energy enters the OPV cell of FIG. 1 through the substrate 100 and passes through the several layers of the cell. Excitons are formed which separate free electrons and holes at the BHJ interface. The exciton formation typically happens at the area of FIG. 1 identified as Distance A. The free electrons and holes are passed out to the outside world as an electric current via connectors coupled to the PEDOT 140 and LiAl 180 layers. A cathode 200 accepts the charge separated electrons and passes them out from the OPV cell, and an anode 210 collects the charge separated holes.

In general, conventional commercial solar cells are heavy, rigid, expensive, and not well suited to diverse roof types. The solar cells are often mounted on a thick glass or rigid metal substrate and covered with a semi-light, transparent, protective glass sheet. Accordingly, conventional commercial solar cells are prone to breakage and difficult to install.

Flexible solar cell technology has been tried, and flexible solar cells can include most of the semi-conductive types of materials. Some commercial flexible solar cells simply affix the photoactive materials onto an appropriate flexible substrate with an adhesive. Silicon single crystal wafers are available in such a configuration. In addition, amorphous and crystalline versions are also available. However, solar cells constructed in this fashion are generally not very flexible and are still likely to crack when flexed by even small amounts. A crack in the underlying structure of a solar cell often results in catastrophic failure. For example, the area of FIG. 1 identified as Short Circuit will cause a complete failure of the cell.

Other more flexible inorganic solid materials may also be used to construct flexible solar cells. Conventionally, the more flexible materials are applied by way of vacuum deposition, chemical vapor deposition or other appropriate means. For example, solar cells of more flexible inorganic materials may be constructed from copper indium gallium diselinide (CIGS), CIS, CdS, CdTe, and many others.

Some flexible solar cells may also allow the integration of inorganic and organic photovoltaic materials. The material combinations are applied to pliable substrates, which allow limited flexing without damage.

Even employing all of the various conventional technologies and materials available, very large solar cell collecting surface areas are required for a typical single family home. A normal roof installation produces only a few thousand watts of DC current when the solar surface is in direct sunlight. The low efficiency range of only 12-20% conversion at the module level is typical of most systems today. In addition, the large surfaces necessary, even when formed with conventional flexible materials, are heavy, expensive, difficult to install, relatively rigid, and relatively fragile.

The problem of inefficient solar arrays may be addressed in part by trying different material selection. For example, the solar excitation wavelength may be exploited by using a mixture or layered structure of several photovoltaic materials. In such a structure, efficiency is increased because the multilayered structure of different materials can absorb more of the solar spectrum.

Many of the problems described above are caused or compounded simply by the conventional processes of manufacturing a solar cell. The fabrication of the simplest semiconductor cell is a complex process. The fabrication must take place under exactly controlled conditions, such as high vacuum and temperatures between 400-1,400 degrees Celsius. Achieving efficient solar energy conversion at low cost and on mass scale is one of the most important technological challenges of our future.

### BRIEF SUMMARY

Photovoltaic cells having a novel geometry and methods of forming the photovoltaic cells are disclosed. According to principles of the present invention, an embodiment of the photovoltaic cell is provided which has a flexible substrate. A first plurality of lines of an N-type semiconductor material are longitudinally positioned on the substrate in a horizontal plane parallel to the plane of the substrate. A second plurality of lines of a P-type semiconductor material are formed in the same horizontal plane as the first plurality of lines of the N-type semiconductor material, and each respective line in the first plurality is adjacent a respective line in the second plurality. Thus, a plurality of pairs of lines of N-type semiconductor material and P-type semiconductor material are formed. Each of the pairs of lines has a common longitudinal junction. A first conductive electrode is positioned on the substrate, and the first conductive electrode has a first plurality of conductive lines coupled to a first common electrical termination. The first plurality of conductive lines extends in contact with the first plurality of lines of N-type semiconductor material. A second conductive electrode is positioned on the substrate. The second conductive electrode has a second plurality of conductive lines coupled to a second common electrical termination. A first electrical terminal is coupled to the first common electrical termination, and a second electrical terminal is coupled to the second common electrical termination.

According to another embodiment a photovoltaic cell forms a barrier layer over a flexible substrate and forms a plurality of parallel lines of N-type semiconductor material directly on the barrier layer. A plurality of parallel lines of P-type semiconductor material are formed directly on the barrier layer and positioned with each line of the plurality of parallel lines of P-type semiconductor material having at least one common longitudinal boundary with one line of the plurality of parallel lines of N-type semiconductor material. A plurality of first conductive bus lines are in longitudinal contact with at least a subset of the plurality of parallel lines of N-type semiconductor material, and a plurality of second conductive bus lines are in longitudinal contact with at least a subset of the plurality of parallel lines of P-type semiconductor material

According to another embodiment a solar cell has a transparent substrate. A first transparent electrode is positioned on the substrate, and the first transparent electrode is comb-shaped by having a plurality of fingers coupled to a common base. The comb-shaped first transparent electrode extends in a horizontal plane parallel to the plane of the substrate. A second transparent electrode is positioned on the substrate, and the second transparent electrode is comb-shaped by having a plurality of fingers coupled to a common base. The comb-shaped second transparent electrode extends in a horizontal plane parallel to the plane of the substrate and also in the same plane as the fingers of the first electrode. The comb-shaped second transparent electrode has having its fingers interdigitated with the fingers of the first transparent electrode. An N-type semiconductor material is positioned adjacent to each side of each finger of the first electrode. A P-type semiconductor material is positioned adjacent to each side of each finger of the second electrode and the P-type semiconductor material is in contact with the N-type semiconductor material positioned adjacent each finger of the first electrode. Electrical terminals are coupled to the respective first and second electrodes.

### BRIEF DESCRIPTION OF THE SEVERAL VIEWS OF THE DRAWINGS

FIG. 1 illustrates a known cross section of an OPV cell.

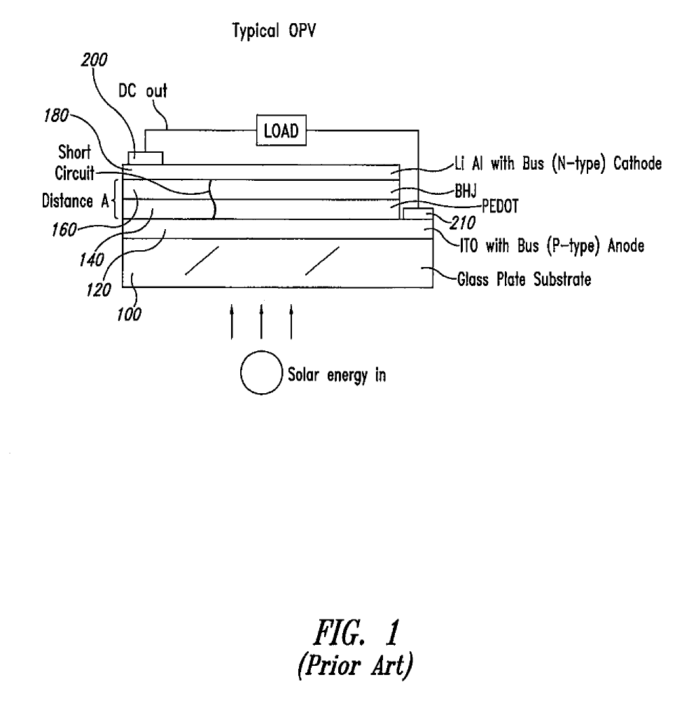

FIG. 2 illustrates a cross-sectional view of an inventive photovoltaic cell.

FIG. 3 is a top view of the photovoltaic cell of FIG. 2.

FIGS. 4A-4H illustrate cross-sectional views of various steps in the process of making the product of FIG. 2.

FIG. 5 illustrates a roll-to-roll manufacturing process of another embodiment of an inventive photovoltaic cell.

FIGS. 6A-6D illustrate cross-sectional views of a photovoltaic cell at various points in the roll-to-roll manufacturing process of FIG. 5.

FIG. 7 illustrates a cross-sectional view of a flexible OPV cell formed with a novel approach to photovoltaic cell geometry.

FIG. 8 illustrates a cross-sectional view of another embodiment of a flexible OPV cell.

### DETAILED DESCRIPTION

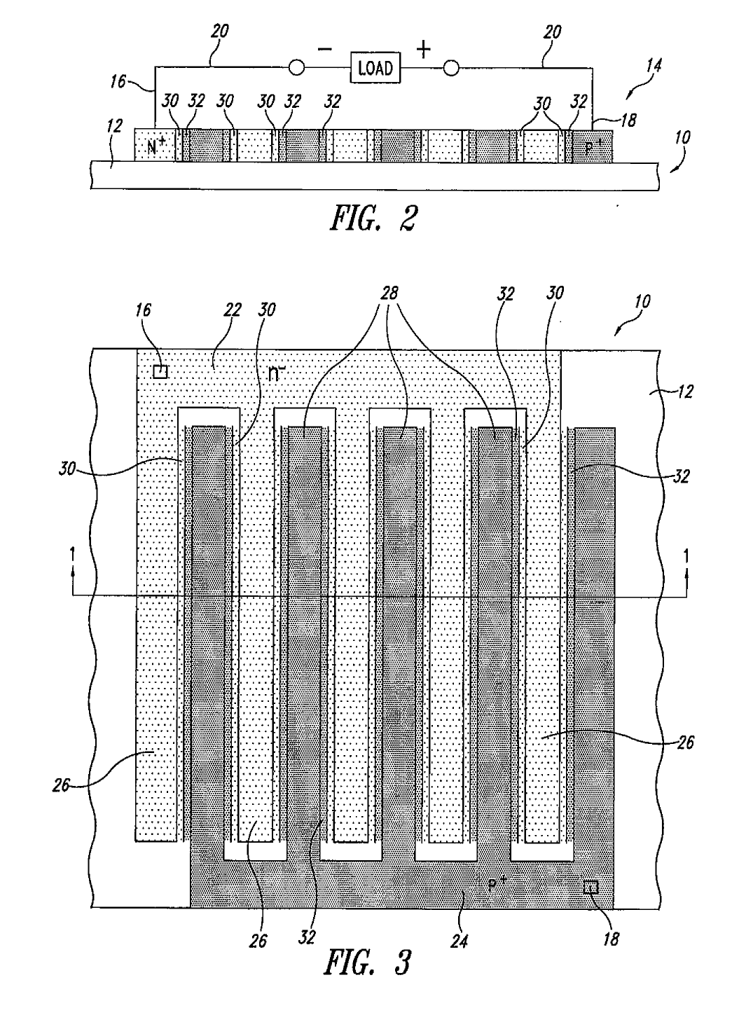

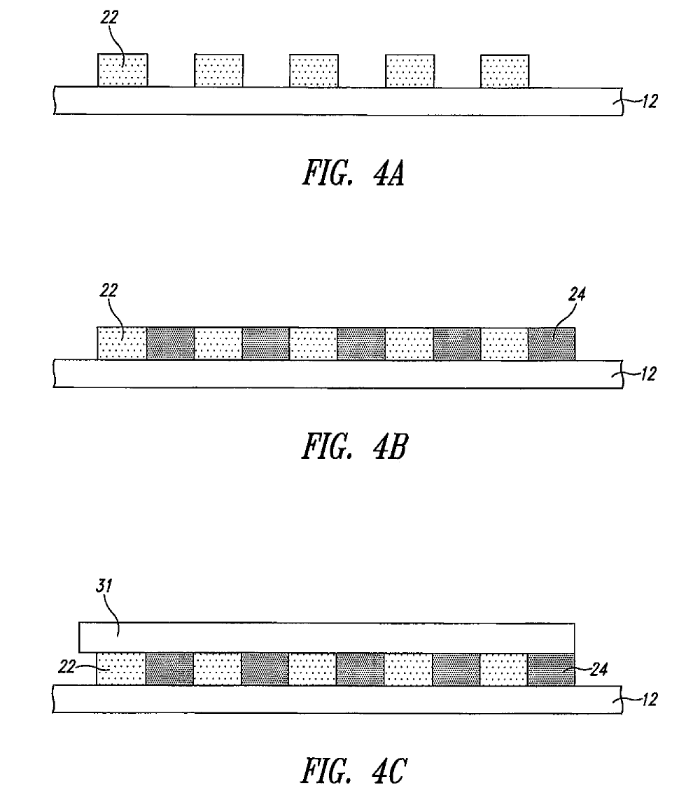

FIGS. 2 and 3 illustrate an embodiment of a photovoltaic cell according to principles of the present invention. In particular, FIG. 2 illustrates a cross-sectional view of an inventive photovoltaic cell. FIG. 3 is a top view of the photovoltaic cell of FIG. 2. The solar cell of FIGS. 2 and 3 may be constructed of organic materials, inorganic materials, or some combination of both.

The particular structures illustrated in FIGS. 2 and 3 may be fabricated using the roll-to-roll technique described herein, by another method described herein, or by other known semiconductor manufacturing processes, preferably at temperatures less than 150° C.

FIGS. 2 and 3 illustrate a solar cell 10 mounted on a plastic substrate 12. FIG. 2 is a cross-section taken along lines 1-1 of FIG. 3. The substrate 12 can be any acceptable substrate with sufficient mechanical strength to hold itself together and provide support for the PN junction solar cell materials mounted thereon. The substrate 12 is preferably flexible plastic having a thickness in the general range of 1 mm. The preferred thickness is in the range of 0.5-1 mm with 0.8 mm being acceptable. The plastic is preferably a transparent plastic of a lightweight composition. The plastic may be of a flexible type but this is not required.

The substrate 12 has deposited thereon a solar cell 14. The solar cell has a plurality of PN junctions spaced longitudinally along the length of the substrate.

The solar cell 14 preferably includes a series of PN junctions horizontally spaced with respect to each other along the substrate 12. In one example, a first transparent electrode 22 is composed of indium tin oxide (ITO). ITO can be provided as an N-type conductor or a P-type conductor and layer 22 is N-type. Natural ITO is transparent and no doping is required in one embodiment. Alternatively, additional doping may be used if desired to change the layer to be N- or P-type or change the relative conductivity within the ITO to make it more highly conductive or change the work function to better accept electrons at the surface boundary of the semiconductor material.

The conductive film is a compound material known as a transparent conductive oxide (TCO). In this example, the material is ITO at about 2500 A thick which is about 85% transparent across the visible spectrum at about 10 ohms square electrical conductivity. Other transparent conductors may be used.

Transparent electrode 24 is a P-type conductive material and in this example is an ion beam assisted sputter deposited thin film of ITO. The ITO is doped P-type with any acceptable dopant. Two of the acceptable dopants are carbon and platinum, although any other dopants which provide lightly doped P-type ITO are acceptable.

A positive terminal 18 is coupled to one of the P electrodes and a negative terminal 16 is coupled to the N electrode. When the solar cell is exposed to light, electricity is generated, which flows through a wire 20 coupled thereto. A load may be coupled to the terminals which uses the electric current produced by the solar cell 14.

Extending from the electrode 22 are a plurality of fingers 26. While five fingers 26 are shown, it will be understood that any number of fingers may be present, including several hundred or thousand in order to provide a high density multi-junction solar cell. A large number of PN junction sites will greatly increase the efficiency of the collection of photons and conversion of the light to electrical current. The P-type electrode 24 also includes a plurality of fingers 28 which are interdigitized with the fingers 26 of the electrode 22, as best seen in FIG. 3.

Turning now to FIG. 2, in between each of the fingers 26 and 28 of the electrodes 22 and 24 are more doped organic or inorganic semiconductor materials, one N-type and the other P-type. More specifically, an N-type doped organic semiconductor 30 is positioned adjacent the N electrode finger 26, and a P doped organic semiconductor 32 is adjacent the P-type doped finger 28. The N- and P-type doped semiconductors 30 and 32 directly contact each other, forming a PN junction at the interface thereof. Each of these semiconductors are more lightly doped than the electrode fingers 26 and 28 to which they are connected.

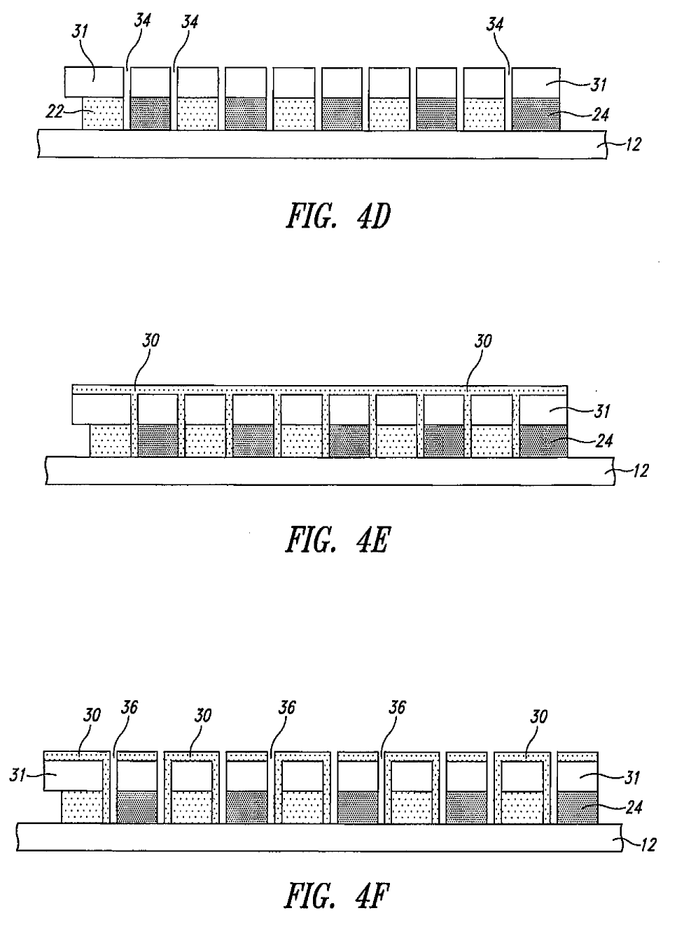

One process of making the flexible solar cell is illustrated in FIGS. 4A-4H, as will now be described, shown generally along line 1-1 of FIG. 3. A starting substrate 12 of acceptable material is provided. Preferably, the substrate 12 is a flexible plastic as previously described, although any transparent material is permissible. A layer 22 of indium tin oxide is provided thereon. The indium tin oxide layer 22 is formed in the shape of the electrode 22 as shown in FIG. 3, previously described. The indium tin oxide layer 22 can be formed in the desired shape by any one of many acceptable techniques. According to a first technique, an ITO layer can be ion beam assisted, then vacuum sputter-deposited through a deposition mask in which apertures have been formed. Alternatively, a blanket layer of ITO can be formed after which it is masked and etched in order to form the electrode 22 as shown in FIG. 3. Additional acceptable techniques for forming the electrode 22 besides the two which have been described may also be used. Next, a P-type layer 24 of ITO is also formed interdigitated between the fingers of the indium tin oxide layer 22 in a manner similar to that shown in FIG. 3. As with indium tin oxide layer 22, the P-type layer of ITO can be formed by any acceptable technique. Sputter deposition through a mask with appropriately registered apertures is one acceptable technique. In addition, blanket conformal deposition to fill the spaces between the electrode 22 with etch-back is also an acceptable technique. The end structure, as shown in FIG. 4B, will have alternating fingers or bands of P- and N-type ITO adjacent to each other and affixed to the flexible substrate 12.

As FIG. 4C illustrates, a mask 31 is applied to the top of the combined structure of layers 22 and 24.

As FIG. 4D illustrates, an aperture 34 is formed adjacent each side of the separate fingers or bands of N-type layer 22, thus forming separated structures between fingers 26 and 28 The aperture 34 may be formed by any acceptable technique of those currently available. In one preferred embodiment, laser ablation is used to form a groove between the ITO fingers of the N-type and P-type material, on either side of the N-type layer 22. Other acceptable techniques include photoresist mask exposure and etch-back techniques. Other techniques known in the art may be used to form the groove opening on each side of the fingers 26 in the N-type layer 22.

As FIG. 4E illustrates, a semiconductor layer 30 is then deposited into the groove which had been previously formed. In one embodiment, the semiconductor layer 30 is an organic solution in the form of a paste, a high viscosity fluid, or other form that can easily enter and fill the groove 34 which has been formed on each side of the fingers 26 of N-type layer 22. There are many known organic semiconductors that can be applied as fluids and then cured to harden and form the end structure of FIG. 4E.

FIG. 4F illustrates the next step in the sequence in which a groove 36 is formed on each side of the P-type finger 28. The groove can be formed by any acceptable technique as previously described with respect to forming the groove on either side of the N-type material.

Next, as shown in FIG. 4G, a P-type semiconductor, preferably an organic semiconductor solution, of transparent of P-type material is formed in the grooves 36. The P-type material is preferably a solution, and may be in the form of a paste or a high viscosity fluid. The P-type material is then cured forming the structure as shown in FIG. 4G.

A number of materials are acceptable for the semiconductor materials of the N-type and P-type. They can be organic or inorganic. According to one embodiment, the N-type semiconductor material is a titanium oxide ruthenium. For example, it may be a porous titanium oxide film with an inorganic material such as ruthenium or other inorganic material such as a Gratzel cell. It may also be a cadmium telluride, cadmium sulfur, carbon 60 or other polymer or molecular semiconductor material. Alternatively, other inorganic materials may be used. For inorganic materials, a copper indium gallium selenium combination may be used. Alternatively, silicon, gallium arsenide or any of the acceptable well known inorganic semiconductor materials may be used. Each of the semiconductor materials will be appropriately doped to be N- and P-type using techniques known in the art. It is preferred that the semiconductors 30 and 32 be somewhat transparent to light, but this is not required.

Subsequently, the mask layer 31 is removed, as shown in FIG. 4H. In one embodiment, the mask layer 31 is a simple blue film laser mask. In such an embodiment, the mask layer 31 may be peeled off to be removed from the layers it covers and takes with it the excess P- and N-type materials which have been applied thereto. In other embodiments, in which the mask is a photoresist, it may be washed away by any of the acceptable techniques.

The final structure shown in FIG. 4H which is similar to that shown in FIG. 2, is a cross-sectional view of a finished semiconductor solar cell device.

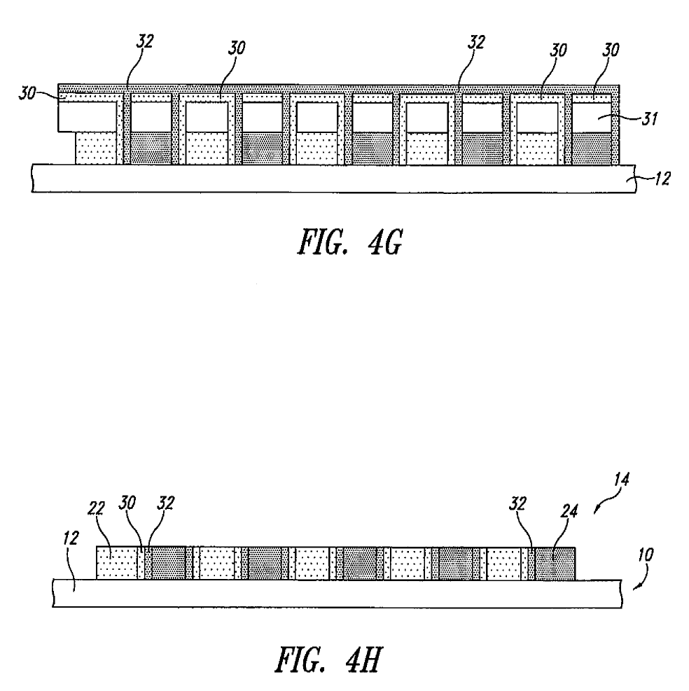

To more completely understand the widespread application of this novel cell design and the inherent advantages it provides, several additional embodiments of the novel geometry will now be described with reference to FIGS. 5-8.

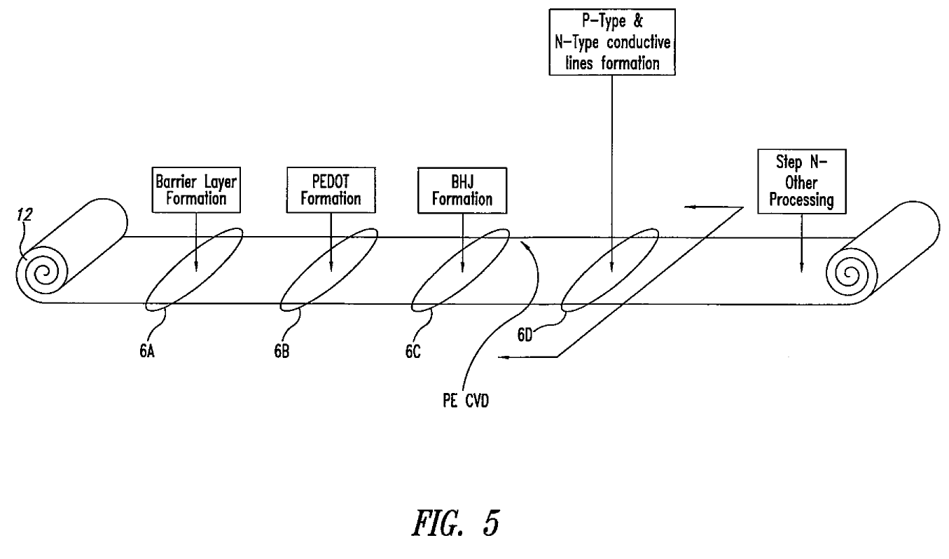

FIG. 5 illustrates a roll-to-roll manufacturing process of another embodiment of an inventive photovoltaic cell. A plastic substrate 12 is wound into a first roll or coil. The substrate 12 is unwound, processed in an assembly line fashion, and re-wound into a second roll or coil. During processing, the exposed areas of the substrate 12 undergo several processing steps as illustrated in FIGS. 6A-6D. At each stage, the substrate goes through another process step so that when the layer 12 is rolled up at the end, a complete photovoltaic cell has been formed and is ready for shipment and use upon being unrolled and exposed to sunlight.

FIGS. 6A-6D illustrate cross-sectional views of a photovoltaic cell at various points in the roll-to-roll manufacturing process of FIG. 5 as explained later herein. The cross sectional view of FIGS. 6A-6D is taken along lines 2-2 of FIG. 5. It is understood that the processing steps of FIGS. 6A-6D represent only one way of manufacturing the novel photovoltaic cell, and many other variations and processes can be used. The figures and descriptions herein are abbreviated to add clarity, however, the specific details needed for each manufacturing step are well known to one skilled in the art.

In one embodiment, a multilayer flexible solar device is formed of organic photovoltaic (OPV) cells. The OPV cells are multilayered devices consisting of electron donor (D) and acceptor (A) materials and these materials can be combined to produce a more efficient cell by forming a bulk hetrojunction (BHJ) structure between conductive films. The conductive films may be a semiconductor, such as polycrystalline silicon, a metal silicide, such as titanium silicide (TiSi), a metal impregnated paste, a metal layer, or the like.

One of the materials of the OPV cell is often a conjugated polymer, but the material may also be another type of organic semiconductor. When the semiconductor absorbs a photon, a bound exciton is formed. When operating efficiently, the exciton diffuses to the interface layer between the semiconductors and is split by electron transfer before it decays. In these complex systems, the distance over which an exciton traverses is only about 4 to 20 nm. Excitons produced by absorbed photons in either the D or A layer dissociate as electrons and holes at the junction interface and diffuse out to the corresponding metal conductors where they are distributed as an electric current.

One efficient high mobility organic P-type donor material is the high-molecular weight, highly regioregular P3HT (Poly(3-hexylthiophene-2,5-diyl). This thermocleavable material associated with alkyl and alkoxy polymers such as MEH-PPV and MDMO-PPV represent some other options for providing electrons in the OPV cell structure. A desirable version of this material is synthesized by the McCollough route and, for example, may be available from Sigma-Aldrich, Catalog number 445703-1G.

There are several materials that can be used to accept electrons from organic semiconductors. A non-limiting group of such materials includes carbon (C₆₀) nanotubes and derivatives, CdSe nanorods and nanoparticles, Titania and Zinc Oxides (TiO2 & ZnO), however, other materials could also be used.

One commonly available acceptor material is a solution derivative of Buckminster fullerene C₆₀, conventionally known as PCBM (methanofullerene Phenyl-C₆₁-Butyric-acid-Methyl-ester). Methanofullerene PCBM was first prepared by Hummelen et al. in 1995 and has become a widely used acceptor material in the field of polymer photovoltaics. A more efficient version, polythiophene PCBM is also in use. Polyiophene PCBM may be available from Sigma Aldrich, Catalog number 684457.

Alternative embodiments of the OPV cell chemistry described herein are also possible. For example, other P-type donor materials may have molecular electron properties further tuned such that the photo conversion efficiency is improved. Such tuning is known in the art. Other semiconductor materials can also be used to accept electrons.

The multilayer flexible solar device of OPV cells may be formed in several ways. In a preferred embodiment, as illustrated in FIG. 5, a roll or coil of clear plastic substrate 12 is provided. The substrate has an approximate thickness of 1-2 mm, and the coil may be several inches or meters in diameter.

As the coil unrolls, the substrate 12 is passed through various chambers or stations where a plurality of processing steps are performed. In this manner, the totality of the material may undergo several processes concurrently in an assembly-line fashion. Various steps of the processing are described with reference to FIGS. 6A-6D, at points indicated in FIG. 5 and in a cross sectional view taken along lines 2-2.

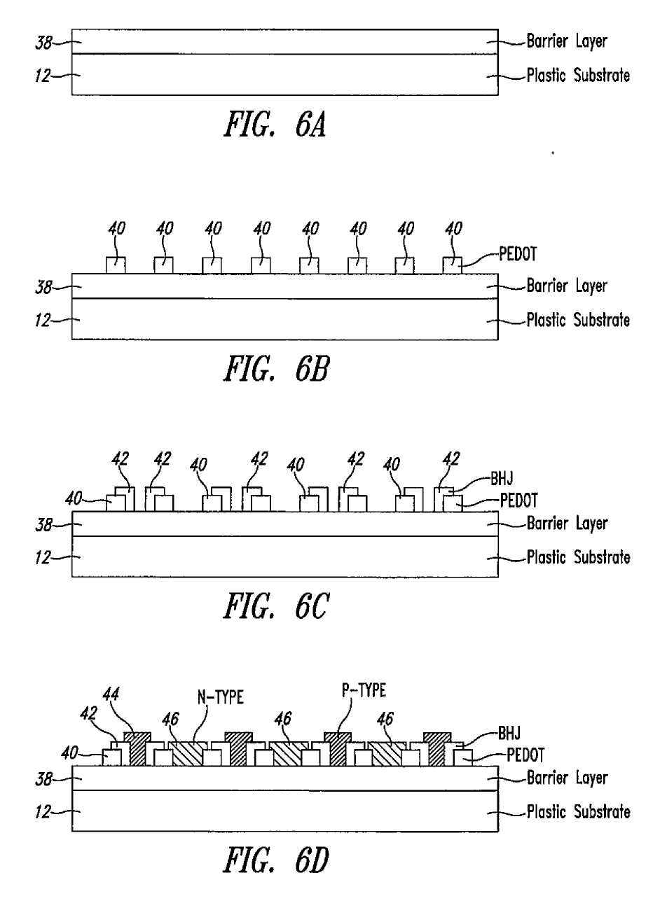

FIG. 7 illustrates a cross-sectional view of a completed flexible OPV cell formed with a novel approach to photovoltaic cell geometry. The OPV cell of FIG. 7 may be formed in many ways, including the roll-to-roll approach according to the processes of FIGS. 5 and 6A-6D, which will now be described.

In a first step of processing starting at stage 6A, shown in FIGS. 5 and 6A, surface impurities on the plastic substrate 12 are removed using a continual plasma discharge method. The cleaning is conducted in an appropriate atmosphere, for example, nitrogen, and the processing atmosphere is contained within a chamber. As the unrolling end of the substrate 12 continues moving away from the coil, the substrate 12 is continuously coated with a barrier layer of Al2O3, SiO2, or some other material, such as a nitride compound. The barrier layer is optional and not used in all embodiments. Depending on the quality of the plastic, however, the barrier layer may provide an improved sealing of uncoated plastic stock to prevent impurities from permeating the sensitive photovoltaic material and diminishing its desirable properties.

The formed barrier layer is shown in FIG. 6A. It may be annealed or cured as needed. The barrier layer is applied to a selected thickness. In some cases, the thickness is a few thousand Angstroms, however, the final thickness may be more or less as determined by the final usage of the cell.

The barrier layer may provide additional desirable properties. For example, the barrier layer can be formed with greater planarity and uniformity than the plastic stock, and thus the barrier layer provides a contiguous film thickness and highly planar surface. The highly planar surface is conducive to the formation of additional structures.

Once the barrier layer has been applied, the substrate 12 then advances to stage 6B, as shown in FIGS. 5 and 6B. At this stage it is imprinted with many fine, parallel lines of a wet solution of a hole transport material 40. The hole transport material 40 may be PEDOT or PEDOT:SS or the like. The hole transport material 40 is well known in the organic electronics field and is often used in organic light emitting diode (OLED) or organic thin film transistor (TFT) designs. An example of such hole transport material may be available from Sigma Aldrich, Catalog number 655201.

The PEDOT structures 40 are shown in the OPV cross section of FIG. 7. PEDOT structures 40 are formed in the processing step of FIG. 6B. The cross section of substrate 12 in FIGS. 6B-6D and FIG. 7 illustrate eight lines of PEDOT material 40. While only a few lines of PEDOT material 40 are illustrated in the figures, it is understood that any number of lines may be formed, including several hundred or thousand. Generally, the predetermined number of lines is based on the specified design or by the dimensional capabilities of the manufacturing equipment.

The PEDOT layer 40 can be formed by a number of techniques. For example, a sealed vacuum chamber can be placed over the strip 12 at stage 6B, forming an air tight seal. The chamber can then be evacuated to a few torr and the deposition carried out in an inert atmosphere, for example of nitrogen or argon. Alternatively, the entire roll to roll substrate 12 can be placed in a vacuum chamber room to avoid contamination and mixing with reactive materials, such as oxygen.

It is further understood that known techniques, such as ion-beam assisted sputter deposition, continuous band printing, and other similar techniques known in the art may be used to form the PEDOT structures 40 and other structures in the OPV cell. Accordingly, the specific steps of formation, including masking, etching, curing, and others are not described, as they are well known.

In OPV cell embodiment now described, one selected parameter of the deposition process is the width of each individual line of hole transport material 40. Another important parameter is the individual line height. Tolerances for line width and height are typically chosen based on how the cell will be used. Generally, a finer line (or thinner width) of each hole transport material 40 area, relative to the total substrate area, will produce a higher density of photoactive material compared to the overall surface area. The higher density of hole transport material 40 tends to produce an OPV cell having a higher efficiency.

The hole transport material 40 may be water based or solvent based. Once the hole transport material 40 is applied, it is dried to produce a homogeneous layer of lines of hole transport material 40 protected from the reactive effects of the ambient atmosphere. Any appropriate chamber able to house the roll-to-roll line and provide these material processes as required to remove the atmosphere may be used for this purpose. In addition, hermetic sealing of the transport material 40 may also be provided.

In a subsequent step of processing, the substrate 12 continues to advance to stage 6C as the hole transport material 40 PEDOT layer dries. After the substrate has the barrier layer and dried PEDOT 40 films formed, interfacing parallel lines of a mixture of organic P-type and N-type materials are applied at stage 6C. The organic P-type and N-type mixture produces a BHJ layer 42. The interfacing lines of the BHJ layer 42 are similarly sized to the dried PEDOT lines 40 and slightly overlap onto the PEDOT lines 40. The BHJ lines 42 are illustrated in FIG. 7. The processing step of forming the BHJ lines 42 are illustrated in FIG. 6C.

As the substrate 12 roll continues to advance by unwinding at one end and rolling up at the other end, the areas having the PEDOT lines 40 and BHJ semiconductive mixture lines 42 are permitted to dry. The drying, or curing, of the BHJ layer 42 is performed in accordance with the type of solvent system used. IR light, heating, or other methods can be used.

After the BHJ layer 42 has cured, the substrate 12 in this area has a patterning of several continuous, parallel, fine lines, wherein each line is formed of two distinct structures. The first structure is formed of PEDOT material 40, and the second structure is formed of BHJ material 42. In a subsequent step of processing, the patterning of the interfacing continuous lines of the combined materials is masked such that a minimum gap or inactive area can be provided between every other pair of lines of materials.

The inactive gap provides an area where P-type conductive lines or N-type conductive lines may be applied. The conductive lines are described with reference to FIGS. 6D and 7. The conductive lines 44 are formed so as to extend between lines of BHJ material 42 down to the barrier layer 38 of the substrate 12. In addition, the conductive lines 44 are formed so as to overfill the gap between lines of BHJ material 42 and extend across part of the top of the BHJ material 42. In a preferred configuration, the conductive line 44 does not extend completely over the top of the BHJ line 42.

In a subsequent step, the previously masked inactive area is unmasked, and the areas now filled with conductive lines 44 are masked. The resulting area of the substrate 12 has a second inactive gap area provided between every other pair of lines of BHJ 42 and PEDOT 40 materials.

The second inactive gap provides an area where P-type or N-type conductive lines may be applied. If the previous step of the process had P-type conductive lines applied, then N-type conductive lines will be applied in the second inactive gap. And vice-versa, if the previous step of the process had N-type conductive lines applied, then P-type conductive lines will be applied in the second inactive gap.

The conductive lines 46 in the second inactive gap are formed so as to extend between lines of PEDOT material 40 down to the barrier layer 38 of the substrate 12. The conductive lines 46 are further formed so as to overfill the gap between lines of PEDOT material 40 and extend across part of the top of the PEDOT material 40. In a preferred configuration, the conductive line 46 does not extend completely over the top of the PEDOT line 40.

The resulting structure will have both P-type conductive lines and N-type conductive lines. A gap separates the two conductive bus lines that have different polarity. In FIGS. 6D and 7, P-type conductive material 44 is illustrated as filling the gap between BHJ lines 44, and N-type conductive material 46 is illustrated as filling the gap between PEDOT lines 40.

In one embodiment, the P-type conductor connects and overlaps the top side of the PEDOT film, and the N-type metal bus line connects and overlaps the BHJ film. The two conductive bus lines are formed in contact with their respective semiconductor line for the length of the substrate 12 roll. In another embodiment, the connections of the P-type and N-type conductors are opposite. It is understood that the formation of conductive lines of ITO, LiAl, CaAl, or other conductive, transparent bus lines may have natural tendencies toward N-type or P-type, however, the present OPV cells are not so limited.

Once the conductive lines are formed, the OPV cell is ready for completion. FIG. 5 shows a step N, where other processing may take place. For example, still within the chamber, the substrate 12 roll may be cut to a desirable finished module size, and busbar type terminations are applied to the conductive lines. The busbar terminations are formed by any practical printing method. Additionally, a top coat of another protective barrier functioning layer is applied, and the device is ready to provide electrical power in the outside world.

One objective of the novel OPV cells described herein is to provide a high density multi-junction solar cell. It is understood that the relative sizes of the lines in FIGS. 5-7 are not to scale. The plastic substrate 12 will be thick compared to other layers, and the line widths will be more narrow than shown to have hundreds of lines. In particular, it is desirable to produce as many electric charge producing junctions as possible. Accordingly, the semiconductor lines of PEDOT and BHJ materials are likely formed with significantly more surface area than the conductive bus lines.

Several alternative embodiments to the substrate roll process may also be implemented. For example, in some cases, the carrier substrate can be grooved with a laser or hot knives to provide first and second continuous line areas. The first and second continuous line area grooves are subsurface to the substrate. The first and second continuous line areas may be filled with hole transport material lines and BHJ material lines having small enough particle size or molecular dimension to cooperate with the formed grooves.

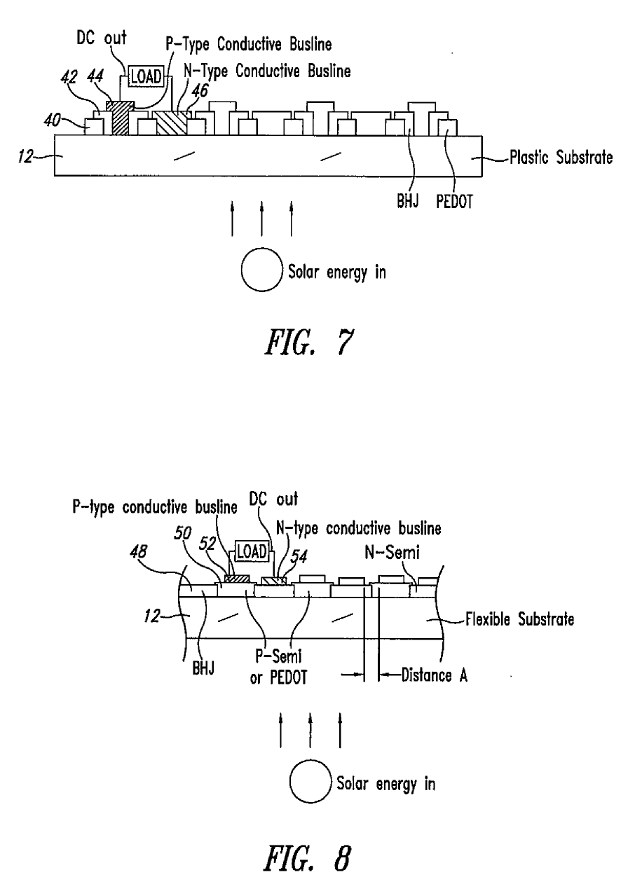

FIG. 8 illustrates a cross-sectional view of another embodiment of a flexible OPV cell. A flexible substrate 12 has formed thereon adjacent lines of alternating BHJ 48 and P-type semiconductor 50 materials. An area identified as Distance A represents the operative area where excitons are formed when presented with photons. Electrons and holes are collected and distributed by conductive bus lines 52, 54. The bus bars 52 and 54 can be on top of all the semiconductor layers or on some sets. The embodiment cross-section of FIG. 8 may be formed using techniques described herein. The geometry of lines of materials may are longitudinally formed upon the substrate of any preselected density and length.

The bus bars 52 and 54 can be P-doped or N-doped, or can be a metal line. Alternatively a reflective metal, such as silver can be placed on either side of the bus bars 52 and 54 to increase conductivity and also increase the solar light passing through the semiconductors array. Any light that reflects from the bus bars 52 and 52 after having passed through the substrate once will pass through it again, increasing efficiency.

In another embodiment individual cells are formed having the conductive lines coupled to provide predetermined operating characteristics. For example, the P-type and N-type individual conductive lines can be connected by each of the two busbars in a particular manner. The manner that the conductive lines are connected will provide either series or parallel connections or a combination of both types to increase voltage or current as desired.

Other alternative embodiments of the substrate roll process construct OPV cells with different materials and on different substrates. The materials may be organic, inorganic, or a combination of both. For example, to produce a cell with only inorganic semi conductive materials, the organic material of the preferred substrate roll process is substituted with inorganic nanoparticles, rod, or other forms in appropriate binder systems. In such processes, known printing processes are used to form the continuous lines of materials.

The novel photovoltaic cell design reduces the probability of current losses by electrical short circuiting through the acceptor and donor photoactive layers between opposing metal conductors as in previous layered designs. The cell construction avoids overlapping metal conductors by way of a linear material deposition design. The techniques described herein allow direct application of materials for efficient roll-to-roll manufacturing, conventional closed chamber manufacturing, and even open air, low temperature manufacturing.

The photoactive materials used in the novel photovoltaic cell design can be organic, inorganic, or a combination of the two. The solar cells described herein can be manufactured with ecologically responsible substrates for ease in recycling or natural bio-consumption. Further, the cells described herein may have substrates formed from inexpensive, previously recycled materials.

In other embodiments, a combination of any organic and inorganic cell is possible including dye cell and concentrating optical approaches. It is also possible to batch process these materials onto individual, more rigid substrates as is well known. Manufactured or depositing can be with any acceptable material and applied by any technology like inkjet, sputtering, laser, continuous band printing, and the like.

In other embodiments, a flexible substrate of a photovoltaic cell may be plastic, glass, or metal. In such embodiments, the substrate may not necessarily be transparent. Instead, the substrate may be completely opaque or even reflective. For example, a substrate of a photovoltaic cell having the interdigitated line geometry described herein may by brushed or polished aluminum, stainless steel, or some other metal. In such embodiments, solar energy enters the cell from the non-metal side.

In the embodiments described herein, several references are made to materials that are clear and/or transparent. It is understood that photovoltaic devices are purposefully designed to accept the entry and penetration of photons. Accordingly, where reference is made to materials being “clear,” “transparent,” or the like, it is understood that the material need only have an acceptable level of light transmissiveness. The materials used in the various embodiments are not necessarily completely clear or transparent, but instead may only be generally translucent such that sufficient light may pass through.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A photovoltaic cell comprising:
a flexible substrate;
a first plurality of lines of an N-type semiconductor material longitudinally positioned on the substrate in a horizontal plane parallel to the plane of the substrate;
a second plurality of lines of a P-type semiconductor material formed in the same horizontal plane as the first plurality of lines of the N-type semiconductor material, each respective line in the first plurality being adjacent a respective line in the second plurality to form a plurality of pairs of lines of N-type semiconductor material and P-type semiconductor material, each of the pairs of lines having a common longitudinal junction;
a first conductive electrode positioned on the substrate, the first conductive electrode having a first plurality of conductive lines coupled to a first common electrical termination, the first plurality of conductive lines extending in contact with the first plurality of lines of N-type semiconductor material;
a second conductive electrode positioned on the substrate, the second conductive electrode having a second plurality of conductive lines coupled to a second common electrical termination;
a first electrical terminal coupled to the first common electrical termination; and
a second electrical terminal coupled to the second common electrical termination.

2. The photovoltaic cell according to claim 1 wherein the flexible substrate is transparent plastic.

3. The photovoltaic cell according to claim 1 wherein the flexible substrate is metal.

4. The photovoltaic cell according to claim 1 wherein the N-type semiconductor material is an organic material.

5. The photovoltaic cell according to claim 1 wherein the P-type semiconductor material is an organic material.

6. The photovoltaic cell according to claim 1 wherein the N-type semiconductor material is an inorganic material and the P-type semiconductor material is an inorganic material.

7. The photovoltaic cell according to claim 1 wherein the N-type semiconductor material and P-type semiconductor material are both in direct contact with the flexible substrate.

8. The photovoltaic cell according to claim 1, further comprising a barrier layer is positioned between the flexible substrate and the N-type semiconductor material and wherein the barrier layer is further positioned between the flexible substrate and the P-type semiconductor material.

9. The photovoltaic cell according to claim 1 wherein the P-type semiconductor material is substantially comprised of a PEDOT material and wherein the P-type semiconductor material is substantially comprised of a BHJ material.

10. A method of forming a photovoltaic cell comprising:
forming a barrier layer over a flexible substrate;
forming a plurality of parallel lines of N-type semiconductor material directly on the barrier layer;
forming a plurality of parallel lines of P-type semiconductor material directly on the barrier layer positioned with each line of the plurality of parallel lines of P-type semiconductor material having at least one common longitudinal boundary with one line of the plurality of parallel lines of N-type semiconductor material;
forming a plurality of first conductive bus lines in longitudinal contact with at least a subset of the plurality of parallel lines of N-type semiconductor material; and
forming a plurality of second conductive bus lines in longitudinal contact with at least a subset of the plurality of parallel lines of P-type semiconductor material.

11. The method of forming the photovoltaic cell according to claim 10 wherein the plurality of parallel lines of N-type semiconductor material and the plurality of parallel lines of N-type semiconductor material are substantially elongated to about the same length.

12. The method of forming the photovoltaic cell according to claim 10 wherein the plurality of parallel lines of N-type semiconductor material are formed having a predetermined width and a predetermined height.

13. The method of forming the photovoltaic cell according to claim 10, further comprising:
forming a first terminal electrically in common with each of the plurality of first conductive bus lines; and
forming a second terminal electrically in common with each of the plurality of second conductive bus lines.

14. The method of forming the photovoltaic cell according to claim 10 wherein the plurality of parallel lines of N-type semiconductor material are formed on a flexible substrate having a thickness of about 0.5 to 2 millimeters.

15. The method of forming the photovoltaic cell according to claim 10 wherein the plurality of parallel lines of N-type semiconductor material are formed of an organic material and the plurality of parallel lines of P-type semiconductor material are formed of an organic material.

16. The method of forming the photovoltaic cell according to claim 10 wherein the plurality of parallel lines of N-type semiconductor material are formed of an inorganic material and the plurality of parallel lines of P-type semiconductor material are formed of an inorganic material.

17. The method of forming the photovoltaic cell according to claim 10 wherein the plurality of parallel lines of N-type semiconductor material are formed of an organic material substantially comprised of a PEDOT material and the plurality of parallel lines of P-type semiconductor material are formed of an organic material substantially comprised of a BHJ material.

18. A photovoltaic cell formed on a flexible substrate having thereon at least two semiconductor materials longitudinally positioned in the same horizontal plane with respect to each other, the at least two semiconductor materials positioned to form a continuous photoactive junction, the continuous photoactive junction in a vertical plane with respect to the substrate.

19. The photovoltaic cell according to claim 18 in which the two semiconductor materials are an N-type semiconductor material and a P-type semiconductor material respectively, and the two semiconductor materials are transparent to light, and the two semiconductor materials are formed as lines on the flexible substrate.

20. The photovoltaic cell according to claim 18 in which the two semiconductor materials are organic materials.
